(19) United States
(12) Patent Application Publication
(10) Pub. No.: US 2020/0292150 A1
(43) Pub. Date: Sep. 17, 2020

(54) REFLECTOR FOR AN LED LAMP

(71) Applicants: JENSEN-TOMY TK LAI, (US); NGL GLOBAL LIMITED, N.T. (HK)

(72) Inventor: Jensen-Tomy TK Lai, Madison, CT (US)

(21) Appl. No.: 16/817,698

(22) Filed: Mar. 13, 2020

Related U.S. Application Data
(60) Provisional application No. 62/796,114, filed on Mar. 15, 2019.

(51) Int. Cl. F21V 7/10; F21V 23/00; F21V 13/00; F21V 19/00; H05K 1/18

(52) U.S. Cl. CPC F21V 7/10; F21V 23/004; F21Y 2115/10; F21V 19/001; H05K 1/181; F21V 13/00

(57) ABSTRACT

Provided is a reflector for an LED lamp, including: a bottom portion having a first surface and a second surface opposite to each other, and a light hole formed to penetrate through the first surface and the second surface of the bottom portion. The first surface is mounted on a printed circuit board (PCB), so that a light source unit disposed on the PCB is located in the light hole and protrudes over the second surface, and a light emitting surface of the light source unit keeps a first distance from the second surface, and a vertical surface of a periphery of the light source unit keeps a second distance from a boundary between the second surface and the reflecting surface. A reflecting surface surrounds around the bottom portion and extends obliquely towards a direction away from the second surface, so that an angle is formed between the reflecting surface and the light emitting surface of the light source unit. In such a way, the light emitted at or near the edge of the light source unit can be effectively output and thus the luminous efficiency thereof can be improved.

### CROSS-REFERENCE TO RELATED APPLICATION

This application claims the priority of U.S. provisional patent application No. 62/796,114, filed on Mar. 15, 2019, which is incorporated herewith by reference.

### BACKGROUND OF THE INVENTION

### 1. Field of the Invention

The present invention relates to a reflector for an LED lamp, more particular to a reflector for a chip on board (COB) LED array lamp capable of effectively reflecting light emitted at or near an edge of an LED light source unit to improve the luminous efficiency thereof.

### 2. The Prior Arts

Generally, a chip on board (COB) LED array used as a light source of a lamp fixture is installed at a bottom of a lamp shade, which directs the light beam emitted from the light source unit toward an opening at a front end of the lamp shade. An inner surface of the lamp shade is provided with a reflector. While the light source unit emits light, a part of the light emits directly outward, and another part of the light is reflected by the reflector and then is emitted out of the lamp shade for enhancing the luminous efficiency thereof.

As shown in FIG. 1, a reflector A of the conventional COB LED array lamp is formed as a tapered shape to construct a tapered reflecting surface A1 on an inner surface thereof. Since there may exist an injection mold release limitation or be convenient for design, a bottom periphery of the reflector A extends downwardly a flange A2 along an axial direction thereof. When a printed circuit board (PCB) B provided with a light source unit C is mounted at a bottom end of the reflector A, the light source unit C is located in a light hole A3 formed by the flange A2, and a light emitting surface C1 of the light source unit C does not protrude over an upper end edge of the light hole A3.

More specifically, after the light source unit C is mounted on the reflector A, a periphery of the light emitting surface C1 of the light source unit C is at most flush with the upper end edge of the light hole A3. Therefore, when the light source unit C emits light, since a diverged angle of the light beam is greater than an inclined angle of the reflecting surface A1 relative to a horizontal plane, the light emitted at or near the edge of the light source unit is blocked by the edge of the light hole A3 (see the arrow in FIG. 1), so that the amount of the light emitted out of the reflector A is reduced, thereby reducing the luminous efficiency.

### SUMMARY OF THE INVENTION

The objective of the present invention is to solve the above problem that the reflector structure of the conventional COB LED array lamp adversely affects the luminous efficiency of the lamp.

In order to achieve the above-mentioned objective, the present invention provides an improved reflector for an LED lamp, the structure of which is modified/adjusted with consideration of the 120° LED beam angle and thus can capture and redirect the light emitted at or near the edge of the COB LED array, thereby reducing the waste of light and improving luminous efficiency.

The technical solution of the present invention is to provide a reflector for an LED lamp, comprising: a bottom portion having a first surface and a second surface opposite to each other, and a light hole formed to penetrate through the first surface and the second surface. The first surface is mounted on a printed circuit board (PCB), so that a light source unit disposed on the PCB is located in the light hole and protrudes over the second surface, and a light emitting surface of the light source unit keeps a first distance from the second surface. A reflecting surface surrounds around the bottom portion and extends obliquely towards a direction away from the second surface, so that an angle is formed between the reflecting surface and the light emitting surface of the light source unit.

Preferably, a vertical surface of a periphery of the light source unit keeps a second distance from a boundary between the second surface and the reflecting surface, so as to provide a larger space for capturing and redirecting the light emitted from the light source unit.

Preferably, the angle formed between the reflecting surface and the light emitting surface of the light source unit may have a range between of 100°-140°, more preferably between 110°-130°, and most preferably be 120°.

Preferably, the light source unit is a chip on board (COB) LED array.

According to the afore-mentioned reflector of the present invention, the light emitted at or near the edge of the light source unit can be captured and redirected to intensively emit outward, thereby not wasting light emitted from the edge of the light source unit and improving luminous efficiency thereof.

### BRIEF DESCRIPTION OF THE DRAWINGS

The present invention will be apparent to those skilled in the art by reading the following detailed description of a preferred embodiment thereof, with reference to the attached drawings, in which:

FIG. 1 illustrates a schematic view showing the light emission of a conventional reflector assembled with a light source unit and a printed circuit board (PCB);

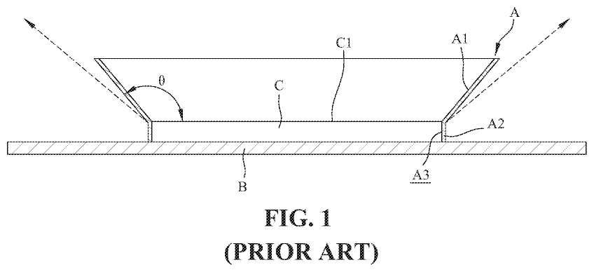

FIG. 2 illustrates a perspective view showing a structural appearance of the reflector of the present invention;

FIG. 3 illustrates a schematic side view showing the structure of the reflector of FIG. 2;

FIG. 4 illustrates a schematic view showing an assembled relationship of the reflector, the light source unit and the PCB of the present invention; and

FIG. 5 illustrates a schematic view showing the light emission of the present invention, in which the light source unit, the PCB and the reflector are assembled together.

### DETAILED DESCRIPTION OF THE PREFERRED EMBODIMENT

The accompanying drawings are included to provide a further understanding of the invention, and are incorporated in and constitute a part of this specification. The drawings illustrate embodiments of the invention and, together with the description, serve to explain the principles of the invention.

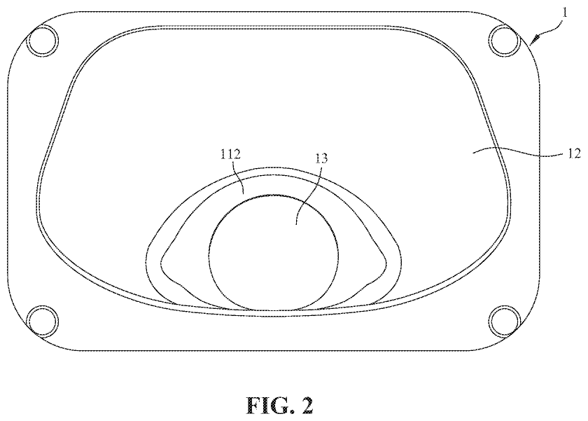

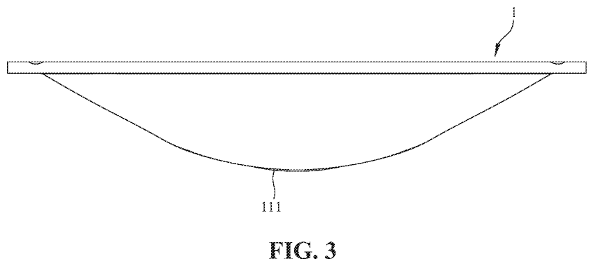

As shown in FIG. 2 to FIG. 5, a reflector 1 according to the present invention is an element for being installed on an inner surface of a lamp shade of an LED lamp for reflecting light emitted from an LED light source unit so as to improve the luminous efficiency thereof.

The reflector 1 includes a bottom portion 11 and a reflecting surface 12, wherein the bottom portion 11 has a first surface 111 and a second surface 112 opposite to each other, and a light hole 13 formed to penetrate through the first surface 111 and the second surface 112 of the bottom portion 11. The first surface 111 is mounted on a printed circuit board (PCB) 2, so that a light source unit 3 disposed on the PCB is located in the light hole 13 and protrudes over the second surface 112. The reflecting surface 12 surrounds around the bottom portion 11 and extends obliquely toward a direction away from the second surface 112, so that an angle θ is formed between the reflecting surface 112 and the light emitting surface 31 of the light source unit 3. Preferably, the angle θ has a range between 100°-140°, more preferably between 110°-130°, and most preferably is 120°. In other words, the reflector 11 is formed as a tapered profile, and an inner surface of the reflector 11 serves as the reflecting surface 12 for reflecting light. The bottom portion 11 is a small diameter end of the tapered profile of the reflector 11, and the light hole 13 is formed in a center of the bottom portion 11.

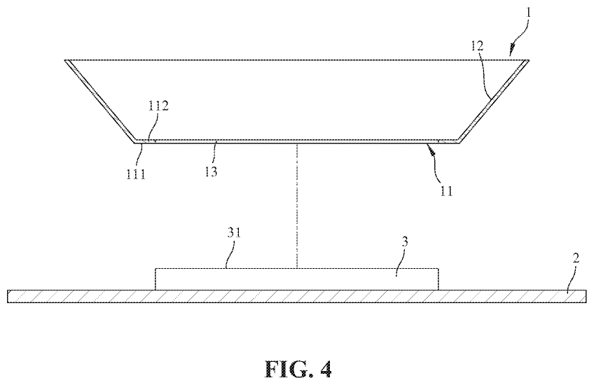

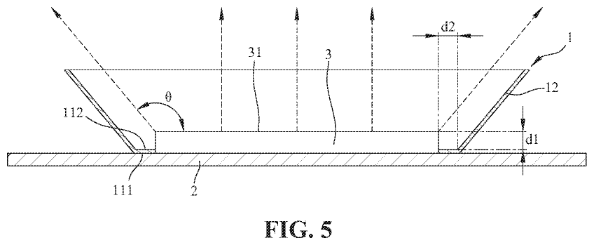

As shown in FIG. 4 and FIG. 5, according to the present invention, a chip on board (COB) LED array is used as the light source unit 3. That is, a plurality of LED chips are packaged in an array manner on a substrate to form the light source unit 3. One side of the light source unit 3 is served as the light emitting surface 31 for emitting light, and another side of the light source unit 3 is mounted on the PCB 2. The PCB 2 has a planned circuit layout thereon. While a current is applied on the PCB 2, the LED chips on the light source unit 3 are controlled to emit light through the circuit.

The reflector 1 is mounted on an inner side of a lamp shade (not shown), and the PCB 2 provided with the light source unit 3 is mounted on a bottom of the lamp shade, so that the light emitting surface 31 of the light source unit 3 disposed in the light hole 13 of the reflector 1 protrudes over the second surface 112. In addition, an inner diameter of the light hole 13 is smaller than a diameter of the second surface 112. After the light source unit 3 penetrates through the light hole 13, the light emitting surface 31 of the light source unit 3 keeps a first distance d1 from the second surface 112, and a vertical surface of a periphery of the light source unit 3 keeps a second distance d2 from a boundary between the second surface 112 and the reflecting surface 12. As such, while the light source unit 3 emits light, the light emitted at or near the edge of the light source unit 3 (see the arrow in FIG. 5) will not be blocked by the edge of the light hole 13, thereby increasing the light output and improving the luminous efficiency. After testing, it can increase the light output and luminous efficiency by about 10%.

The above description is only for explaining the preferred embodiments of the present invention, and is not intended to limit the present invention. Therefore, any form of the changes should be included in the scope of the invention as claimed.

What is claimed is:

1. A reflector for an LED lamp, comprising:
a bottom portion having a first surface and a second surface opposite to each other, and a light hole formed to penetrate through the first surface and the second surface of the bottom portion, wherein the first surface is mounted on a printed circuit board (PCB), so that a light source unit disposed on the PCB is located in the light hole and protrudes over the second surface, and a light emitting surface of the light source unit keeps a first distance from the second surface; and
a reflecting surface surrounding around the bottom portion and extending obliquely towards a direction away from the second surface, so that an angle is formed between the reflecting surface and the light emitting surface of the light source unit.

2. The reflector according to claim 1, wherein a vertical surface of a periphery of the light source unit keeps a second distance from a boundary between the second surface and the reflecting surface.

3. The reflector according to claim 1, wherein the angle has a range between 100°-140°.

4. The reflector according to claim 3, wherein the angle has a range between 110°-130°.

5. The reflector according to claim 4, wherein the angle is 120°.

6. The reflector according to claim 1, wherein the light source unit is a COB LED array.
